(19) United States
(12) Patent Application Publication
(10) Pub. No.: US 2011/0134303 A1
(43) Pub. Date: Jun. 9, 2011

(54) IMAGE PICKUP DEVICE AND MANUFACTURING METHOD THEREOF

(75) Inventors: Kyu-dong JUNG, Suwon-si (KR); Woon-bae KIM, Suwon-si (KR); Min-seog CHOI, Seoul (KR)

(73) Assignee: SAMSUNG ELECTRONICS CO., LTD., Suwon-si (KR)

(21) Appl. No.: 12/783,101

(22) Filed: May 19, 2010

(30) Foreign Application Priority Data
Dec. 7, 2009 (KR) 10-2009-0120642

(51) Int. Cl. H04N 5/225; H01L 31/18

(52) U.S. Cl. 348/340; 438/65; 348/E05.024; 257/E31.001; 257/E31.127; 257/E31.11

(57) ABSTRACT

An image pickup device and a manufacturing method thereof are disclosed. The image pickup device includes a printed circuit board (PCB), an image sensor module, an optical lens module, a fluidic lens module, and a shutter module. The image sensor module is disposed over the printed circuit board and electrically connected to interconnection pads on the PCB. The optical lens module is disposed over the image sensor module and includes one or more lenses. The fluidic lens module is disposed over the optical lens module, has a variable focus and is electrically connected to interconnection pads on the PCB. The shutter module is disposed over the fluidic lens module, and is electrically connected to remaining interconnection pads on the PCB. The fluidic lens module and the shutter module may be connected to the interconnection pads through bumped plate springs.

### CROSS-REFERENCE TO RELATED APPLICATION

This application claims the benefit under 35 U.S.C. §119(a) of Korean Patent Application No. 10-2009-120642, filed on Dec. 7, 2009, the disclosure of which is incorporated by reference in its entirety for all purposes.

### BACKGROUND

1. Field

The following description relates to an image pickup device and a manufacturing method thereof.

2. Description of the Related Art

Following the development of digital technologies, digital convergence is becoming increasingly popular. Digital convergence is most prominent in the field of media and communications. A representative digital convergence product is a so-called “camera phone” where an image pickup module such as a digital camera or a digital camcorder is combined with a mobile phone. Image pickup devices are also installed in various other electronic devices including laptop computers, Personal Digital Assistants (PDAs), robots, etc. in addition to mobile phones.

As mobile electronic devices are generally required to be small and slim line, demands for small, light-weight and low-cost image pickup devices are increasing accordingly. Also, demands on high pixel density and high performance of image pickup devices that are to be installed in mobile electronic devices, or robots are increasing, and in order to meet these demands, various additional functions are being installed in image pickup devices. For example, various modules for providing additional functions, such as Auto Focus (AF), Zoom-in/out, mechanical shuttering and the like, are being added to such image pickup devices. All or some of such modules that are added to the image pickup device may be electronic devices.

### SUMMARY

The following description relates to a small, light-weight, slim line and low-cost image pickup device, and a manufacturing method thereof.

The following description also relates to a small-sized image pickup device capable of achieving high pixel density, high performance and excellent productivity, and a manufacturing method thereof.

The following description also relates to an image pick-up device having improved electrical connections between electrical components and a simple electrical wiring structure, and a manufacturing method thereof.

In one exemplary aspect, there is provided an image pickup device including a printed circuit board (PCB), an image sensor module, a fixed optical system and one or more electronic devices. The PCB has a first interconnection pad and a second interconnection pad. The image sensor module is disposed over the PCB, and is electrically connected to the first interconnection pad. The fixed optical system is disposed over the image sensor module and includes one or more lenses to guide light onto the image sensor module. The electronic devices are disposed over the fixed optical system, are electrically connected to the second interconnection pad, and include optical elements. The image pickup device further includes a housing disposed on the printed circuit board, within which the image sensor module and the wafer scale lens module are fixed, wherein a plate spring is fixed at a lateral wall of the housing.

In another exemplary aspect, there is provided an image pickup device including a printed circuit board (PCB), an image sensor module, an optical module, a fluidic lens module and a shutter module. The printed circuit board (PCB) has inner interconnection pads, a pair of first outer interconnection pads, and a pair of second outer interconnection pads. The image sensor module is mounted on the PCB and electrically connected to the inner interconnection pads. The optical lens module is disposed over the image sensor module and includes one or more lenses to guide light to be received by the image sensor module. The fluidic lens module is disposed over the optical lens module, includes a variable focus element and is electrically connected to the pair of first outer interconnection pads. The shutter module is disposed over the fluidic lens module to pass or block light to be incident to the optical lens module, and is electrically connected to the pair of second outer interconnection pads. The image pickup device further includes a housing within which the image sensor module and the optical lens module are fixed, the housing disposed between the inner interconnection pads and the pairs of first and second outer interconnection pads on the PCB.

In another exemplary aspect, there is provided a method of manufacturing an image pickup device, including: preparing a printed circuit board (PCB) having inner interconnection pads, a pair of first outer interconnection pads and a pair of second interconnection pads; mounting an image sensor module on the PCB, and electrically connecting the image sensor module to the inner interconnection pads; fixing a housing having two pairs of connectors attached to lateral walls thereof, wherein the housing is positioned between the inner interconnection pads and the pairs of first and second outer interconnection pads; disposing an optical lens module over the image sensor module inside the housing, the optical lens module including one or more lenses to guide light to be received by the image sensor module; disposing a fluid lens module over the housing, and electrically connecting the fluid lens module to the pair of first interconnection pads through a first of the two pairs of connectors, the fluid lens module having a variable focus; and disposing a shutter module to pass or block light to be incident to the optical lens module, over the fluidic lens module, such that the shutter module is electrically connected to the pair of second outer interconnection pads through a second of the two pairs of connectors.

Other objects, features and advantages will be apparent from the following description, the drawings, and the claims.

### BRIEF DESCRIPTION OF THE DRAWING

FIG. 1A is a perspective view showing an exemplary image pickup device.

FIG. 1B is an exploded, perspective view of the image pickup device illustrated in FIG. 1A.

FIG. 1C is a cross-section view of the image pickup device illustrated in FIG. 1A.

FIG. 2A is a plan view showing an exemplary fluidic lens module included in the image pickup device.

FIG. 2B is a cross-sectional view of the fluidic lens module cut along an II-II′ line of FIG. 2A.

FIG. 2C is a cross-sectional view of the fluidic lens module when a driving voltage is applied to the fluidic lens module.

FIG. 3 is a view for explaining an exemplary method for arranging a fluidic lens module in an image pickup device.

FIG. 4A is a perspective view showing an exemplary shutter module that can be installed in an image pickup device, wherein the shutter module blocks light.

FIG. 4B is a perspective view of the shutter module of FIG. 4A when the shutter module passes light.

FIG. 5 is a view for explaining exemplary directions in which a shutter module is arranged in an image pickup device.

FIG. 6 is a cross-sectional view showing an exemplary image pickup device including through type via connectors.

FIG. 7 is a perspective view showing an exemplary outer type via connector.

Elements, features, and structures are denoted by the same reference numerals throughout the drawings and the detailed description, and the size and proportions of some elements may be exaggerated in the drawings for clarity and convenience.

### DETAILED DESCRIPTION OF EXEMPLARY EMBODIMENTS

The detailed description is provided to assist the reader in gaining a comprehensive understanding of the methods, apparatuses and/or systems described herein. Various changes, modifications, and equivalents of the systems, apparatuses, and/or methods described herein will likely suggest themselves to those of ordinary skill in the art. Also, descriptions of well-known functions and constructions are omitted to increase clarity and conciseness.

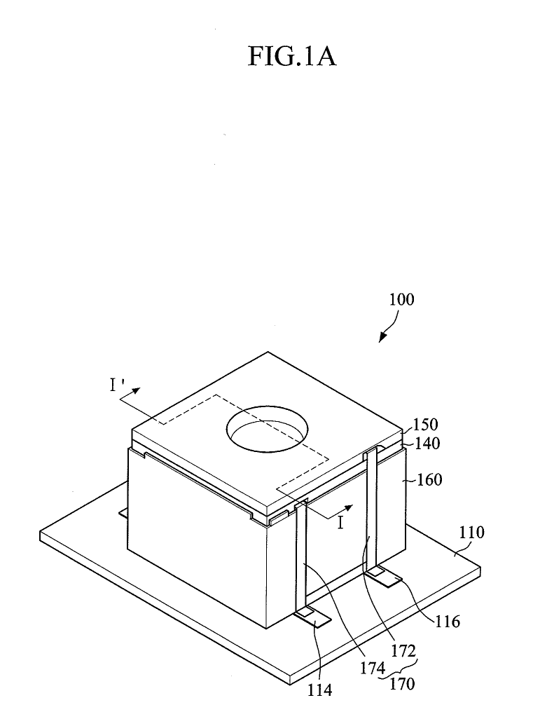

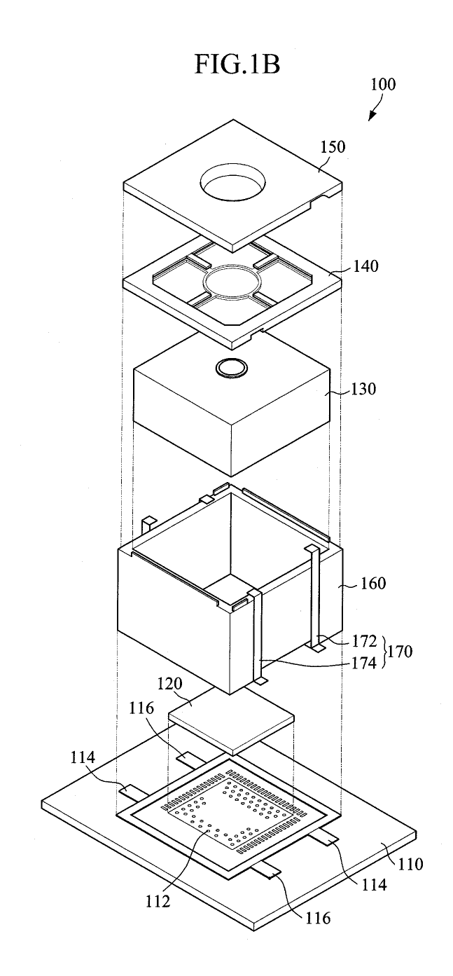

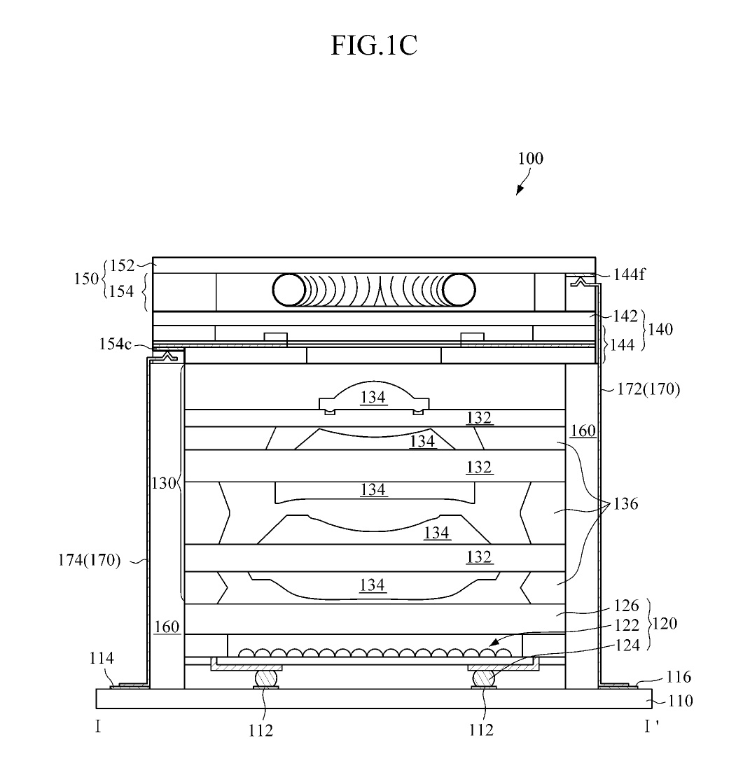

FIG. 1A is a perspective view showing an exemplary image pickup device 100, FIG. 1B is an exploded, perspective view of the image pickup device 100, and FIG. 1C is a cross-section view of the image pickup device 100 taken along a line I-I′. Referring to FIGS. 1A, 1B and 1C, the image pickup device 100 includes a printed circuit board (PCB) 110, an image sensor module 120, an optical lens module 130, a fluidic lens module 140, a shutter module 150, a housing 160 and connectors 170. In FIGS. 1A, 1B and 1C, the modules of the image pickup device 100 are shown, for convenience of description, to be exaggerated in size, shape, thickness, etc.

Referring to FIGS. 1A, 1B and 1C, the modules other than the PCB 110 may have a rectangular parallelepiped shape collectively or individually. In more detail, the image pickup device 100 may be a structure where the modules 120, 130, 140 and 150, each having a rectangular parallelepiped shape, are assembled in a rectangular parallelepiped housing 160 as a frame on the PCB 110. Since the rectangular parallelepiped modules 120, 130, 140 and 150 each may be manufactured to be small and slim line in a wafer level, the image pickup device 100 also may be manufactured to be small and slim line as a whole.

The PCB 110 functions as a base substrate to electrically and mechanically connect the image pickup device 100, specifically, the image sensor module 120, the fluidic lens 140 and the shutter module 150 to external electronic devices, a power supply, etc. The PCB 110 is not limited to any specific type and may be made of a flexible material or a rigid material. The PCB 110 may be a single integrated substrate or a substrate assembly consisting of two or more substrates.

The PCB 110 may have a plurality of interconnection pads 112, 114 and 116 to make electrical connections to electronic devices that are disposed thereover. Some of the interconnection pads 112, 114 and 116, for example, the inner interconnection pads 112 may be used to make electrical connections to the image sensor module 120, and the others, for example, the outer interconnection pads 114 and 116 may be input/output electrodes to apply a driving voltage to the modules 140 and 150. The names, locations and connection relationships of the interconnection pads 112, 114 and 116 are only exemplary, and in the current embodiment, the interconnection pads 112, 114 and 116 are classified into the inner interconnection pads 122 and the outer interconnection pads 114 and 116 with respect to the position of the housing 160. However, it is also possible that the interconnection pads 112, 114 and 116 all are disposed inside or outside the housing 160 or that interconnection pads to connect to the image sensor module 120 are disposed outside the housing 160 while interconnection pads to connect to the fluidic lens 140 and the shutter module 150 are disposed inside the housing 160.

The image sensor module 120 is mounted on the PCB 110. The image sensor module 120 receives light passing through the optical lens module 130, thus forming an image thereon. The formed image is processed by a predetermined signal processor, for example, a digital signal processor (DSP), and then stored in an external storage and/or output to a display.

The image sensor module 120 may include a photosensitive cell array 122 and interconnection terminals 124. The photosensitive cell array 122 receives incident light to form an image, and may be a Complementary Metal-Oxide Semiconductor (CMOS) image sensor or a Charge Coupled Device (CCD). The interconnection terminals 124 are used to connect the image sensor module 120 to an external power supply or an external processor, and may have a predetermined shape corresponding to a package type of the image sensor module 120. In the current embodiment, the interconnection terminals 124 may be implemented in the form of solder balls so that a Surface Mounting Technology (SMT) can be applied thereto. The image sensor module 120 may be packaged to be mounted on the PCB 110 such that the interconnection terminals 124, such as solder balls, contact the inner connection pads 112 on the PCB 110.

The image sensor module 120 may further include a cover glass 126 that is spaced a predetermined distance upward from the photosensitive cell array 122. In the current embodiment, the cover glass 126 is shown as a member of the image sensor module 120, for convenience of description, but the cover glass 126 may be a member of the optical lens module 130 or provided as an element which is separate from both the image sensor module 120 and the optical lens module 130. The cover glass 126 is put into the housing 160 to shield and protect the photosensitive cell array 122, thus preventing dust or moisture from adhering to the photosensitive cell array 122. The cover glass 126 may be made of a transparent substrate (for example, a glass substrate) in order for incident light to pass through the cover glass 126 with minimal losses and reach the photosensitive cell array 122. Above or below the cover glass 126, an optical coating layer, such as an optical low-pass filter, a chrominance filter, an IR filter or the like, may be additionally provided.

The optical lens module 130 is disposed over the image sensor module 120. The optical lens module 130 is an example of an imaging optical system having one or more lenses to guide light received by the image sensor module 120. The optical lens module 130 may have a rectangular parallelepiped shape to be inserted into and coupled with the housing 160. The optical lens module 130 may be composed of a plurality of quadrilateral substrates 132 stacked on top of each other and lens elements 134 attached on one or both sides of the substrates 132.

The substrates 132 may be spaced a predetermined distance from each other by spacing members 136 such as spacers. The substrates 132 may be made of a transparent material such as glass. A light-transmitting region of each substrate 132, corresponding to a light path, may be an inner region surrounded by a light screening film made of an opaque material or may be an opening in the center portion of each substrate 132. Each lens element 134 is attached and fixed on one or both sides of each substrate 132, and may be made of thermosetting transparent polymer, UV curing polymer, or glass or the like. Each layer (a substrate 132 and a lens element 134 attached to one or both sides of the substrate 132) constructing the optical lens module 130 may be a wafer level lens module, which is manufactured by forming an array using a wafer, stacking wafer arrays and dicing it into individual components.

Generally, an Auto Focus (AF) function of an image pickup device has been implemented by driving an optical lens module using a Voice Coil Motor (VCM), a piezo motor, an electro-magnetic motor, etc. In other words, conventionally, in order to change the optical characteristics of an optical lens module, a method of varying the interval between lenses or between the optical lens module and an image sensor has been mainly utilized. However, in this case, a separate space is needed outside the optical lens module and components for the motor, and the individual lenses and/or the entire optical lens module, which makes an assembly process more complicated and leads to increases in size, thickness, weight, and cost of components of a finally manufactured image pickup device.

Unlike the conventional case, in the image pickup device 100 according to the current embodiment, the interval between the lenses included in the optical lens module 130 and/or the interval between the optical lens module 130 and the image sensor module 120 is fixed. The optical lens module 130 is a fixed imaging optical system that cannot change its optical characteristics by itself. Accordingly, the image pickup device 100 requires neither any motor nor any other components for driving a lens module, and also does not need any separate spare space.

Instead, the optical pickup device 100 includes one or more electronic units 140 and 150 to vary the optical characteristics of the optical lens module 130, which are disposed over the optical lens module 130. For example, one or both of the fluidic lens module 140 and shutter module 150 may be placed over the optical lens module 130. The fluidic lens module 140 is an exemplary electronic unit which changes the shape of a lens instead of moving the lens, thus varying the focal distance of the optical lens module 130. Utilization of the fluidic lens module 140 provides various functions, such as VariFocus, Auto Focus, Zoom-in/out, Macro, etc., to the image pickup device 100 with a fixed optical system. The shutter module 150, which is a light blocking unit which passes light only for a predetermined time period, passes or blocks light to be incident to the optical lens module 130. The shutter module 150 also may adjust its opening for light transmission to control the amount of light to be received by the image sensor module 120. Hereinafter, detailed descriptions for the fluidic lens module 140 and shutter module 150 will be given.

The fluidic lens module 140 may have a structure where a transparent elastic optical membrane is attached to a frame filled with an optical fluid. The fluidic lens module 140 includes an actuator to make the optical fluid flow, and a pair of electrode pads to apply a driving voltage to the actuator. When a predetermined driving voltage is provided by the pair of electrode pads, the actuator is driven to cause the optical fluid to flow, thus applying a predetermined pressure from the flowing optical fluid to a lens surface corresponding to the optical membrane. The predetermined pressure varies the shape of the lens surface, that is, the curvature of the lens surface, thereby changing the focal distance. Like the optical lens module 130, the fluidic lens module 140 may be manufactured by forming an array using a wafer and dicing it into individual modules.

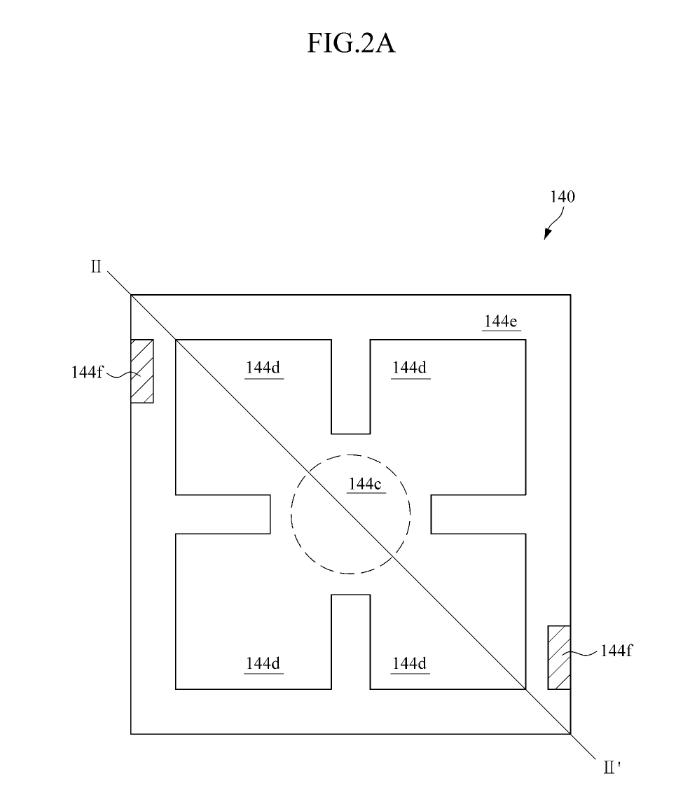

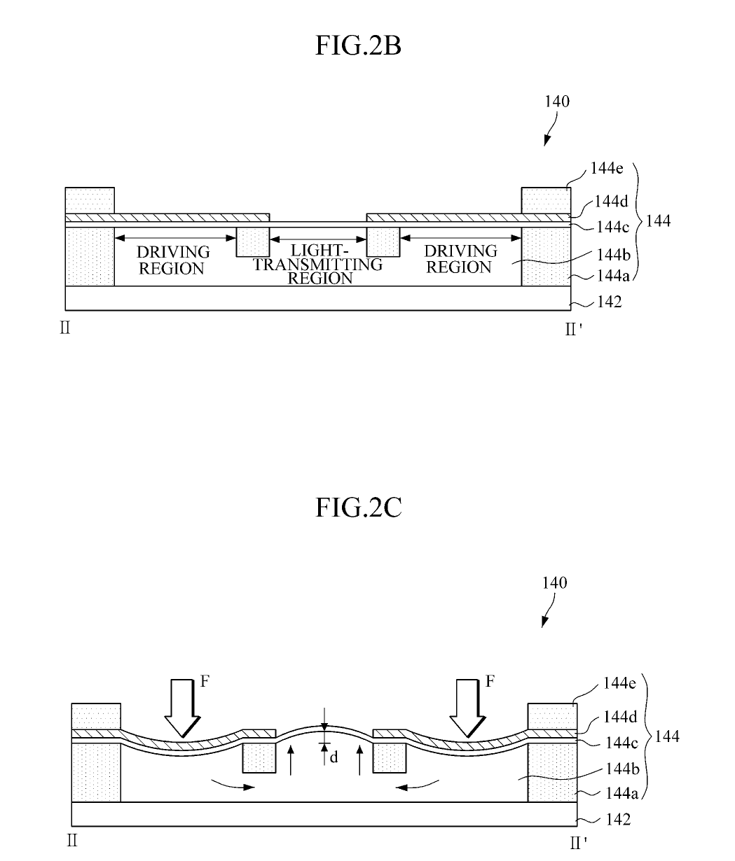

FIGS. 2A, 2B and 2C are plan and cross-sectional views showing an exemplary structure and operation of the fluidic lens module 140. FIGS. 2B and 2C are cross-sectional views of the fluidic lens module 140 cut along a line II-II′ of FIG. 2A, wherein FIG. 2B corresponds to when no driving voltage is applied to the fluidic lens module 140 and FIG. 2C corresponds to when a predetermined driving voltage is applied to the fluidic lens module 140. In FIGS. 2A, 2B and 2C, for convenience of description, the fluidic lens module 140 is shown upside down compared to the structures shown in FIGS. 1A, 1B and 1C. The arrangement direction of the fluidic lens module 140 will be described later. Referring to FIGS. 2A, 2B and 2C, the fluidic lens module 140 includes a substrate 142 and a lens part 144. The lens part 144, which corresponds to all components other than the substrate 142, may include a spacer frame 144a, an optical fluid 144b, an optical membrane 144c, an actuator 144d, a fixed frame 144e and a pair of electrode pads 144f. The fluidic lens module 140 may be manufactured in the form of an array on a glass wafer.

The substrate 142 may be made of an arbitrary transparent material. For example, the substrate 142 may be a glass substrate or a transparent polymer substrate. The substrate 142 fixes the fluidic lens module 140 onto another module (for example, an image-forming optical system) of the image pickup device 100 and also acts as the bottom of the lens part 144. The substrate 142 may function as one element, together with the spacer frame 144a and the optical membrane 144c, of a frame in which the optical fluid 144b is filled and sealed.

The spacer frame 144a defines a predetermined inner space in which the optical fluid 144b can be filled. The spacer frame 144a may be made of an opaque material such as Si or the like. The inner space that is restricted by the spacer frame 144a may be partitioned into a light-transmitting region and a driving region. In more detail, the upper portion of the inner space may be partitioned into a light-transmitting region and a driving region by the spacer frame 144a, while the lower portion thereof may have no partitions. The open lower portion of the inner space allows free flow of the optical fluid 144b inside the spacer frame 144a.

The light-transmitting region is a region through which incident light passes in the lens part 144. The driving region is a region to which a driving power is applied to vary the shape of the light-transmitting region. In more detail, as illustrated in FIG. 2C, when a predetermined driving voltage is applied by the pair of electrode pads 144f to apply a predetermined pressure (a pressure F from the actuator 144d) onto the driving region from above, the optical fluid 144b in the driving region moves toward the light-transmitting region. Thus, the amount of optical fluid below the light-transmitting region increases, and accordingly the light-transmitting region protrudes upwardly (that is, forms a convex lens shape with a protrusion of height d). Here, it will be appreciated by those skilled in the art that a pressure from the actuator 144d to be applied to the driving region may be adjusted to control the transformation amount of the light-transmitting region (for example, the protrusion of height d).

The optical fluid 144b is filled in the inner space restricted by the spacer frame 144a. The optical fluid 144b may be an arbitrary material which is transparent and non-volatile, exhibits physically and chemically stable properties within a use temperature range of the image pickup device and has low viscosity to ensure excellent fluidity. The optical fluid 144b may be silicon oil, hydrocarbon oil, esters oil, ethers oil, polyether oil, perfluorinated polyether oil, etc. Specifically, a material having a high degree of polymerization at low viscosity and a material having repulsive force to the material of the optical membrane may be used as the optical fluid 144b.

The optical membrane 144c is attached to the top of the spacer frame 144a, thus sealing the optical fluid 144b to prevent it from leaking from the inner space restricted by the spacer frame 144a. The optical membrane 144c may be made of a material (for example, Polydimethylsiloxane (PDMS)) having relatively low adhesive power since its outer surface may be exposed to contact air and foreign substances. Meanwhile, since the inner surface of the optical membrane 144c contacts the optical fluid 144b, the optical membrane 144c may be made of a material which is repulsive to the optical fluid 144b. The optical membrane 144c is formed as a single-layered structure made of a single material satisfying all the above-described requirements or as a double-layered structure made of different materials which in combination satisfy the above-described requirements.

The actuator 144d is placed on the optical membrane 144c, in correspondence to the driving region. If the driving region is divided into a plurality of sections, the actuator 144d also may be provided as a plurality of units correspondingly. The actuator 144d may be bonded on the optical membrane 144c by predetermined bonding means. The actuator 144d stays parallel to the substrate 142 when no driving voltage is applied thereto, and bulges downward to apply a pressure to the optical fluid 144b when a driving voltage is applied thereto. That is, when the actuator 144d bulges downward, the optical fluid 144b below the driving region flows to the light-transmitting region, so that the optical membrane 144c of the light-transmission region, that is, the lens surface becomes convex. The actuator 144d may be a multi-layered, electro-active polymer actuator.

In order to apply a driving voltage to the actuator 144d, the pair of electrode pads 144f are connected to the actuator 144d. For example, the pair of electrode pads 144f may be disposed at both facing sides of the actuator 144d that is a rectangular shape. The electrode pads 144f electrically connect to the interconnection pads 114 of the PCB 110 (see FIG. 1C) through predetermined connectors. The connectors (denoted by a reference number 172 in FIG. 1A) that are electrically connected to the pair of electrode pads 144f will be described in more detail later.

The fixed frame 144e may be disposed on the actuator 144d. The fixed frame 144e is used to firmly fix the optical membrane 144b and/or the actuator 144d to the spacer frame 144a. The fixed frame 144e may be made of silicon (Si) or any other appropriate material. The fixed frame 144e may be formed in an arbitrary, appropriate shape to be able to expose the entire light-transmitting region, a portion of the actuator 144d and the pair of electrode pads 144f. Also, the fixed frame 144e has a predetermined height at which the lens surface can never contact any other components even though the light-transmitting region is expanded to the maximum, in the form of a convex lens.

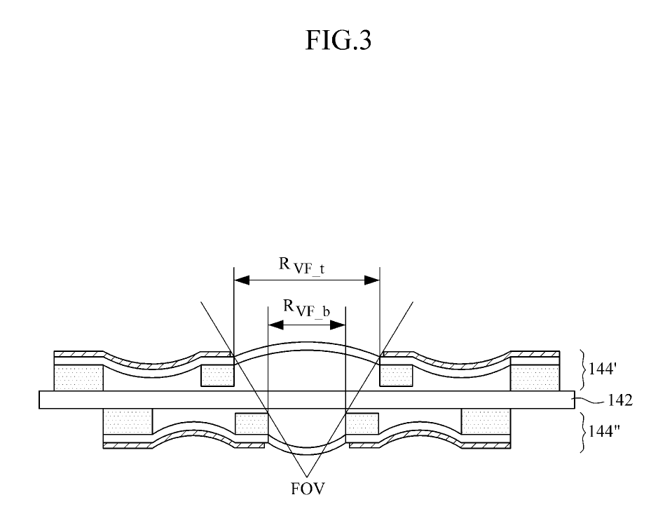

FIG. 3 is a view for explaining an exemplary method for arranging the fluidic lens module 140 in the image pickup device 100. As illustrated in FIG. 3, the fluidic lens module 140 may be arranged such that a lens part 144′ faces upward against the substrate 142 or downward against the substrate 142. However, under the same field of view (FOV), the lens part 144′ may have a larger light-transmitting region or a longer light-transmitting diameter than the lens part 144″ (R_{VF}_{_{—}}_{b}<R_{VF}_{_{—}}ₜ). In more detail, the lens part 144′ may have a larger lens size than the lens part 144″. An increase in size of the light-transmitting region also leads to an increase in size of the corresponding driving region.

Accordingly, in the case of the lens part 144′, a larger amount of optical fluid has to move from the driving region to the light-transmitting region than in the case of the lens part 144″ in order to obtain the same height of protrusion. For this, a greater driving power, that is, a higher driving voltage has to be applied to the driving region. Furthermore, movement of a large amount of optical fluid increases a time required for the optical fluid movement, which results in a reduction in response speed of the fluidic lens module 140. In consideration of these, the arrangement of the lens part 144″ which faces toward the image sensor module 120 against the substrate 142 is superior for operation of the fluidic lens module 140 in terms of efficiency, low driving voltage requirements and quick response speed.

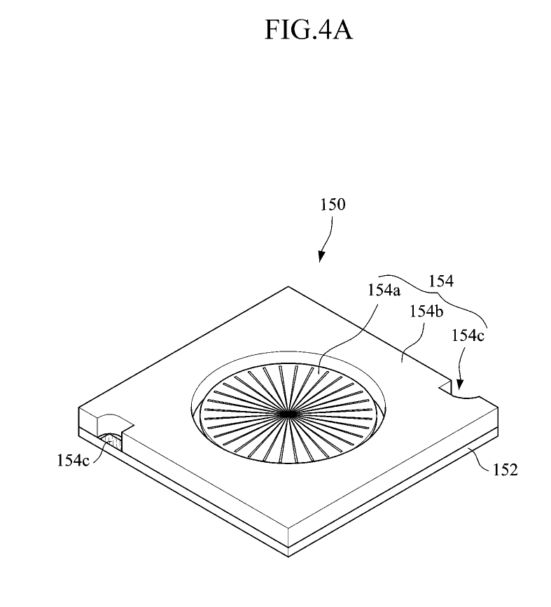

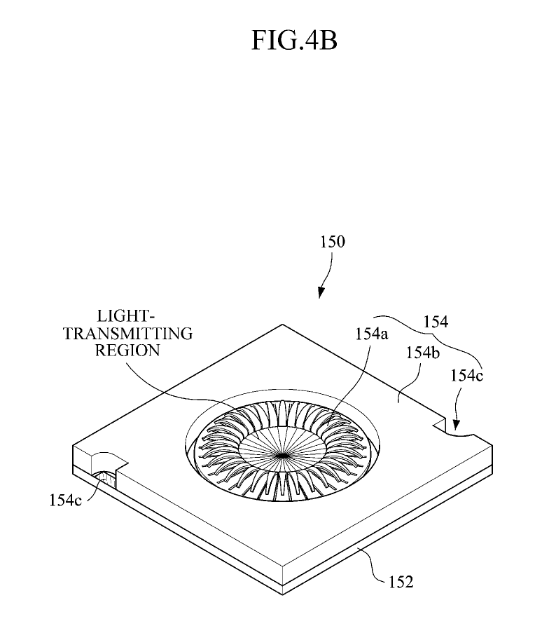

Thereafter, referring to FIGS. 1A, 1B and 1C, the shutter module 150 can be disposed over the optical lens module 130. FIGS. 4A and 4B are views for explaining an example of the shutter module 150, wherein FIG. 4A corresponds to when the shutter module 150 blocks light and FIG. 4B corresponds to when the shutter module 150 passes light. Referring to FIGS. 4A and 4B, the shutter module 150 includes a substrate 152 and a roller-up actuator 154. The shutter module 150 also may be manufactured in the form of an array on a glass wafer.

The substrate 152 has a light-transmitting region. The light-transmitting region is a portion of the substrate 152, which passes light when roll-up blades 154a of the roll-up actuator 154 are rolled up (see FIG. 4B) and which is covered by the roll-up blades 154a when the roll-up blades 154a are driven and flattened (see FIG. 4A). The light-transmitting region of the substrate 152 is positioned in correspondence to the light-transmitting region of the fluidic lens module 144, on an optical path of the optical lens module 130 which is an image-forming optical system. The substrate 152 may be wholly made of a transparent material, or a part of the substrate 152 including the light-transmitting region may be made of a transparent material. The substrate 152 may be a glass substrate, but is not limited to this. That is, the substrate 152 may be formed of any other transparent material, such as quartz, plastic, silica and the like.

On one surface of the substrate 152, a transparent electrode (not shown) is formed. The transparent electrode may be made of a transparent conductive material, for example, Indium Tin Oxide (ITO), ZnO, SnO₂, CNT, conductive polymer, etc. The transparent electrode electrically connects to one of a pair of electrode pads 154c. The transparent electrode may be formed on the entire surface of the light-transmitting region, or may be formed with a predetermined pattern in the light-transmitting region.

The roll-up actuator 154 includes a plurality of roll-up blades 154a. One end of the roll-up blades 154a are fixed on the substrate 152 or a spacer 154b along the circumference of the light-transmitting region. The roll-up blades 154a electrically connect to the other one of the pair of electrode pads 154c. The roll-up blades 154a stay in a rolled-up state (see FIG. 4B) as long as no driving voltage is applied. When the roll-up blades 154a are rolled up, the light-transmitting region of the substrate 152 is exposed to pass incident light. Meanwhile, when a predetermined driving voltage is applied between the roll-up blades 154a and transparent electrodes on the substrate 152, the roll-up blades 154a are flattened (see FIG. 4A). In this state, the light-transmitting region of the substrate 152 is covered by the roll-up blades 154a to block incident light.

The roll-up actuator 154 further includes the spacer 154b and the pair of electrode pads 154c. The spacer 154b is made of an opaque material to prevent light from passing through the other regions of the substrate 152 excluding the light-transmitting region. The spacer 154b has a great predetermined height to prevent interference from occurring between the spacer 154 and adjacent components when the roll-up blades 154a are flattened from the rolled-up state or rolled-up from the flattened state. The spacer 154b is shaped to expose the pair of electrode pads 154c and the shape of the spacer 154b is not limited.

The pair of electrode pads 154c may be disposed at lateral portions of the facing side of the substrate 152 that is formed to have a rectangular shape. The pair of electrode pads 154c electrically connect to the transparent electrode and the roll-up blades 154a, respectively, which are formed on the substrate 152. Also, the pair of electrode pads 154c electrically connect to the interconnection pads 116 of the PCB 110 through the connectors 170 (see FIG. 1C), which will be described later.

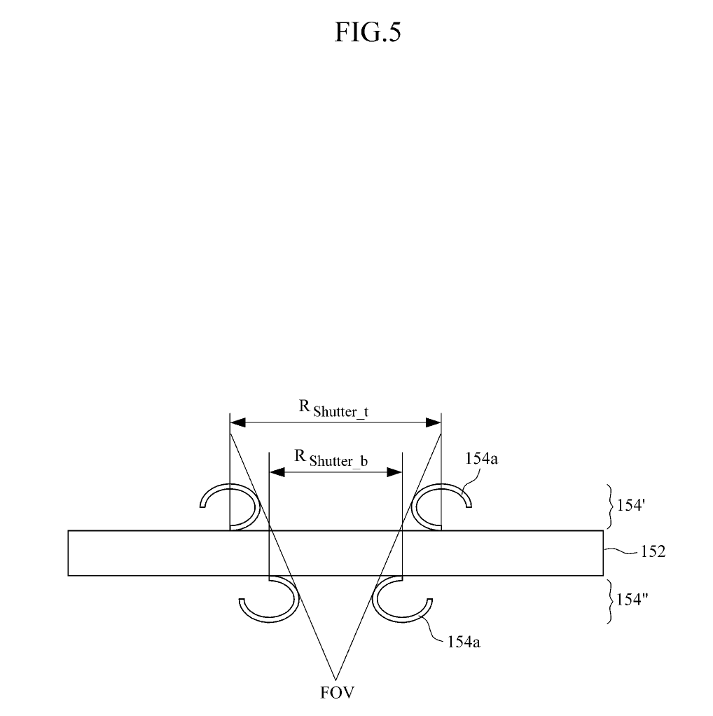

FIG. 5 is a view for explaining exemplary directions in which the shutter module 150 is arranged in the image pickup device 100. As illustrated in FIG. 5, in the shutter module 150, a roll-up actuator 154′ may face upward against the substrate 152, that is, to be opposite to the image sensor module (120 of FIG. 1C), or face downward against the substrate 152, that is, toward the image sensor module 120. However, like the fluidic lens module 140, under the same field of view (FOV), the roll-up actuator 154′ may have a larger light-transmitting region or a longer light-transmitting region diameter than the roll-up actuator 154″, such that Rₛₕᵤₜₜᵣ_{_{—}}_{b}<R_{Shutter}_{_{—}}ₜ.

In more detail, the roll-up actuator 154′ may have a larger size than the roll-up actuator 154″ and accordingly, the light-transmitting region that is to be covered by the roll-up blades 154a should be wide enough to accommodate the roll-up actuator 154′. As a result, in the case of the roll-up actuator 154′, the length of the roll-up blades 154a used to wholly cover the light-transmitting region is larger than that of roll-up actuator 154″, and accordingly there is more movement of the roll-up blades 154a during shuttering. Furthermore, a greater driving power is needed to drive the larger sized roll-up blades 154a, which accompanies a need for a higher driving voltage. Moreover, the greater movement of the larger roll-up blades 154a increases a time used to completely cover the light-transmitting region, which results in a reduction in response speed of the shutter module 150. In consideration of these, the arrangement of the roll-up actuator 154″ which faces toward the image sensor module 120 against the substrate 152 may be used for operation of the shutter module 150 in terms of efficiency, low driving voltage requirements and quick response speed.

Returning again to FIGS. 1A through 2C, the housing 160 is disposed on the PCB 110. The housing 160 functions as a frame to accommodate and fix the modules 120, 130, 140 and 150 stacked on the PCB 110. All the modules 120, 130, 140 and 150 may be accommodated inside the housing 160, or some of the modules 120, 130, 140 and 150 may be accommodated inside the housing 160 and the remaining module(s) may be mounted and fixed on the housing 160. For this, the housing 160 may be a rectangular parallelepiped shape having an empty inner space and having open top and bottom faces. Also, the housing 160 may have a predetermined height enough to accommodate the image sensor module 120 and the optical lens module 130 therein. The inner lateral walls of the housing 160 are shaped in correspondence to the outer shapes of the modules 120 and 130 to be accommodated inside the housing 160, and the top of the lateral walls of the housing 160 may be shaped to fix the modules 140 and 150 to be mounted on the housing 160. Alternatively, the housing 160 may further include a member for fixing the modules 140 and 150.

The modules 140 and 150 that are disposed over the optical lens module 130 electrically connect to some of interconnection pads of the PCB 110, for example, to the interconnection pads 114 and 116. For these electrical connections, the image pickup device 100 includes the connectors 170 to electrically connect the electrode pads 144f and 154c of the electronic devices 140 and 150 to the interconnection pads 114 and 116. The connectors 170 have a vertically extending shape to electrically connect the modules 140 and 150 disposed over the optical lens module 130 to the PCB 110 which is a base substrate. That is, the electrode pads 144f and 154c and the interconnection pads 114 and 116 are electrically connected to each other through the connectors 170 that form a vertical 3D interconnection.

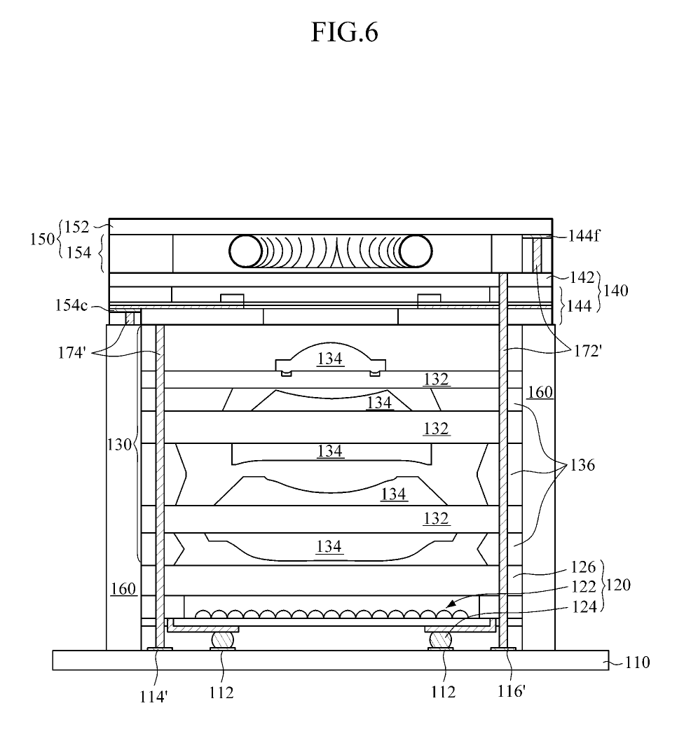

Each connector 170 shown in FIGS. 1A through 1C is an example of an outer type via connector which is disposed outside the modules 110, 120, 130 and 140 that are accommodated inside the housing 160, that is, each connector 170 is an outer type via connector that extends vertically outside the housing 160. However, each connector 170 may be a through type via that penetrates the modules 110, 120, 130 and 140 that are accommodated inside the housing 160. FIG. 6 is a cross-sectional view showing another exemplary image pickup device including through type via connectors 172′ and 174′. Referring to FIG. 6, the connector 172′ connects to the electrode pad 144f of the fluidic lens module 140 and penetrates the optical lens module 130 (including at least one substrate, a spacer, etc.), the image sensor module 120, etc., thus electrically connecting to the interconnection pad 114′ of the PCB 110. Meanwhile, the connector 174′ connects to the electrode pad 154c of the shutter module 150 and penetrates the fluidic lens module 140, the optical lens module 130, the image sensor module 120, etc., thus electrically connecting to the interconnection pad 116′ of the PCB 110.

In the case of utilizing the through type via connectors 172′ and 174′, no separate external connector needs to be provided, which contributes to reduce the entire size of a finally manufactured image pickup device, compared to the case of utilizing outer type via connectors. In addition, since it is possible to form vias after completely assembling modules or to assemble modules using vias, improved alignment is ensured. However, on the other hand, there may be great difficulties in forming vias in the substrates of individual modules when the substrates are made of glass, etc. that can be easily broken. Besides, it may not be easy to fill the vias with a conductive material, which may increase manufacturing costs and cause current loss due to high resistance or contacts with other conductive members.

Whereas, in the case of utilizing the outer type via connectors 170, as illustrated in FIGS. 1A, 1B and 1C, it is possible to manufacture the outer type via connectors 170 in a manner to add conductive structures (for example, plate springs) to the existing structure. However, the outer type via connectors 170 may increase the entire size of the image pickup device 100 and deteriorate alignment. As an advantage, the outer type via connectors 170 may be manufactured by a simpler method than a manufacturing method of through type via connectors, which leads to a reduction of manufacturing costs. Also, the outer type via connectors 170 can be made of a material with low resistance, thus minimizing current loss.

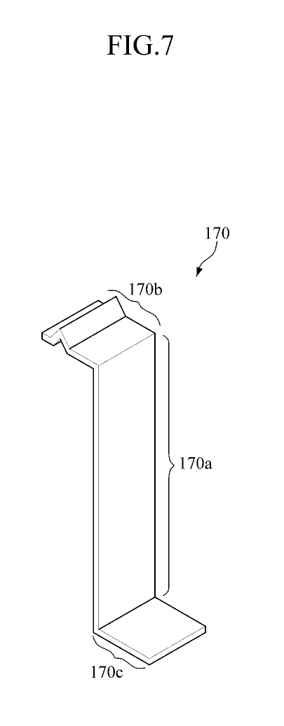

FIG. 7 is a perspective view showing an exemplary outer type via connector 170. Referring to FIG. 7, the connector 170 includes an extending part 170a corresponding to a body and connection parts 170b and 170c corresponding to both ends of the body. This distinguishing of the connection parts from the extending part is to classify their functions, and does not meaning that they are necessarily physically separate elements. The extending part 170a has a predetermined length corresponding to the distance between the interconnection pads 114 and 116 of the PCB 110 and the electrode pads 144f and 154c of the electronic devices 140 and 150. Also, the connection parts 170b and 170c respectively contact both the interconnection pads 114 and 116 of the PCB 110 and the electrode pads 144f and 154c of the electronic devices 140 and 150.

The connector 170 may be made of a conductive material such as metal, etc. For example, the connector 170 may be a plate spring made of aluminum, copper, steel, etc., however, the connector 170 may be made of any other materials. When electrode pads or connection pads of other electronic devices press and contact the connection parts 170a and 170b of the plate spring, the contact between the connection parts 170b and 170c and the electrode pads/connection pads may continue to be maintained by spring tension. In addition, in order to more firmly ensure the contact between the connection pats 170b and 170c and the electrode pads/interconnection pads, a part of any one of the connection parts 170b and 170c may protrude outward (see 170b). In this specification, a plate spring with a connection part whose portion protrudes outward is referred to as a “a bumped plate spring”. In the bumped plate spring, all connection parts may have protruding portions or any one of connection parts may have a protruding portion.

The connector 170, which may be such a bumped plate spring, may be fixed at a lateral wall of the housing 160. In more detail, the connector 170 may be fixed at a lateral wall of the housing 160 through the extending part 170a. The connector 170 is shown to be attached to an outer lateral wall of the housing 160, however, this is only exemplary. For example, the connector 170 may be attached to an inner lateral wall of the housing 160 or inserted into a lateral wall of the housing 160. Meanwhile, the connector 170 fixed at an outer lateral wall of the housing 160 may function to fix the modules 140 and 150 that are disposed over the housing 160.

As described above, the pair of electrode pads 144f and 154c may be positioned to face each other, at lateral portions of the electronic devices 140 and 150 that are disposed over the optical lens module 130. In this case, a pair of connectors 170 also may be fixed at lateral sides of the housing 160. When more electrode devices are mounted, more pairs of connectors may be provided whose extending parts have different lengths. For example, as illustrated in FIG. 1C, the connector 170 may include a first connector 172 which is connected to the electrode pad 144f of the fluidic lens module 140 and a second connector 174 which is connected to the electrode pad 154c of the shutter module 150. When the shutter module 150 is disposed on the fluidic lens module 140, the length of the extending part of the first connector 172 is shorter than that of the extending part of the second connector 174. Also, in this case, the electrodes pads 144f and 154c in the electronic devices 140 and 150 may be positioned at different locations so that the connectors 172 and 174 do not overlap.

As described above, in the image pickup device 100, one or more modules 140 and 150 for changing the optical characteristics of the optical lens module 130 are disposed over the optical lens module 130. Alternatively, all or a part (for example, the fluidic lens module 140) of the modules 140 and 150 can be disposed inside the optical lens module 130, more particularly, between a plurality of substrates (lens elements) included inside the optical lens module 130. In this case, since the fluidic lens module 140 is positioned close to the image sensor module 120, the size of the lens part of the fluidic lens module 140 can be reduced, which allows use of a low driving voltage and ensures a quick response speed.

However, since a variable optical system is inserted inside the optical lens module 130 which is a fixed, image-forming optical system, there may be difficulties in acquiring high-quality images throughout all focus distances due to aligning errors or height errors between substrates (lens elements). Also, since the fluidic lens module 140 is positioned inside the optical lens module 130, the manufacturing process is complicated accordingly. Meanwhile, the image pickup device where the electronic devices 140 and 150 are disposed over the optical lens module 130 may prevent such picture-quality deterioration due to aligning errors or height errors. In addition, the image pickup device 100 has excellent extendibility since other electronic devices can be added to change the optical characteristics of the optical lens module 130 as necessary.

In the image pickup device 100, the fluidic lens module 140 is positioned on the optical lens module 130 and the shutter module 150 may be positioned on the fluidic lens module 140. The image pickup device 100 according to the current embodiment does not exclude the case where the fluidic lens module 140 and the shutter module 150 are disposed in the reverse order, however, the above-described arrangement of the fluidic lens module 140 and the shutter module 150 makes the electronic devices 140 and 150 function more efficiently.

As described above, since the fluidic lens module 140 uses movement of an optical fluid sealed therein to change the shape of a light-transmitting region, a greater driving force is needed than that needed to directly drive the roll-up blades 154a of the shutter module 150. Accordingly, positioning the fluidic lens module 140 as close as possible to the image sensor module 120 reducing the entire device size contributes to improving energy efficiency and achieves a quick response speed.

Also, the shutter module 150 functions to pass or block incident light. The function of the shutter module 150 is not related to the distance to the optical lens module 140. Meanwhile, the fluidic lens module 140 varies the curvature of the lens surface to control an index of refraction of incident light, thereby changing the direction of light to be incident to the optical lens module 130. Accordingly, positioning the fluidic lens module 140 as close as possible to the optical lens module 130 allows efficient controlling of variations in optical characteristics and also allows fine control on the optical characteristics.

Hereinafter, a method of manufacturing the image pickup device 100 will be described with reference to FIGS. 1A, 1B and 1C. Details for the individual modules 110, 120, 130, 140, 150, 160 and 170 included in the image pickup device 100 will not be described to avoid repeated descriptions, and only descriptions regarding a process of manufacturing the image pickup device 100 by assembling the modules 110, 120, 130, 140, 150, 160 and 170 will be given.

Modules or devices 110, 120, 130, 140, 150, 160 and 170 to be included in the image pickup device 100 have been prepared in advance through separate manufacturing processes. Among them, the image sensor module 120, the optical lens module 130, the fluidic lens module 140 and the shutter module 150 may be prepared by forming an array with a wafer and dicing it in into individual components. Alternatively, all or some of the image sensor module 120, the optical lens module 130, the fluidic lens module 140 and the shutter module 150 may be diced at the same time after being stacking together on a wafer.

First, a PCB 110 is prepared. The PCB 110 may include inner interconnection pads 112 and outer interconnection pads 116 on its upper surface. Then, an image sensor module 120 is mounted on the PCB 110 using a general semiconductor packaging process. Here, interconnection terminals 124 of the image sensor module 120 contact the inner interconnection pads 112.

Next, a housing is disposed and fixed on the PCB 110 while accommodating the image sensor module 120 therein. The housing 160, which has a rectangular parallelepiped shape having open top and bottom faces, may be disposed such that the lateral walls of the housing 160 are positioned between the inner interconnection pads 112 and outer interconnection pads 116. Two pairs 172 and 174 of connectors are fixed at the outer lateral walls of the housing 160, wherein two connectors in each pair have different lengths of extending parts. Also, the two connectors in each pair are fixed on facing lateral walls of the housing 160. The housing 160 is assembled such that connection parts corresponding to the lower ends of the connectors 170 contact the outer interconnection pads 114 and 116.

Thereafter, an optical lens module 130 is inserted inside the housing 160. As a result, the optical lens module 130 can be placed on a cover glass 126 of the image sensor module 120. Then, a fluidic lens module 140 is mounted on the optical lens module 130. The fluidic lens module 140 may be mounted such that its lens part 144 faces downward below a substrate 142. Then, a shutter module 150 is mounted on the fluidic lens module 140, and the shutter module 150 also may be mounted such that its roll-up actuator part 154 faces downward below a substrate 152. Upon assembling the fluidic lens module 140 and the shutter module 150, their respective electrode pads 14f and 154c contact the connection parts of the connectors 172 and 174.

Then, a shield may be provided to surround the image pickup device 100. The shield can have a rectangular parallelepiped shape, like the housing 160, having an open bottom face. The top of the shield may be opened at a portion corresponding to an optical path. The shield, which is a kind of case to protect the image pickup device 100 from foreign objects, moisture, etc., has a size enough to accommodate at least the image pickup device 100 excluding the PCB 110 therein.

As described above, since the image pickup device has a structure where electronic devices (the fluidic lens module, the shutter module, etc.) are stacked sequentially over an optical lens module, the image pickup device may be manufactured at low cost to be small, slim line and light-weight, while achieving high pixel density and high performance. Furthermore, the image pickup device has excellent productivity since it can be manufactured in a manner to assembly individual components manufactured in advance. Also, since the image pickup device forms electrical wirings using connectors, such as bumped plate springs, etc., electronic devices that are mounted on the image pickup device can have excellent electrical connectivity through a simple wiring structure.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An image pickup device comprising:
a printed circuit board (PCB) comprising a first interconnection pad and a second interconnection pad;
an image sensor module disposed over the PCB and electrically connected to the first interconnection pad;
a fixed optical system disposed over the image sensor module and comprising one or more lenses; and
one or more electronic devices disposed over the fixed optical system, comprising one or more optical elements and electrically connected to the second interconnection pad.

2. The image pickup device of claim 1, wherein the one or more electronic devices comprise at least one of:
a fluidic lens module comprising an optical element having a variable focal length, and
a shutter module.

3. The image pickup device of claim 1, wherein the one or more electronic devices comprises more than one electronic device and the more than one electronic device comprises:
a fluidic lens module comprising an optical element having a variable focal length, and
a shutter module disposed over the fluidic lens module.

4. The image pickup device of claim 1, wherein the one or more electronic devices comprises a fluidic lens module comprising a substrate and a lens part mounted on the substrate,
wherein the fluidic lens module is disposed such that the lens part is between the image sensor module and the substrate, and
wherein the lens part has a variable focal length.

5. The image pickup device of claim 1, wherein the one or more electronic devices comprises a shutter module comprising a substrate, and a roll-up actuator disposed on the transparent substrate,
wherein the roll-up actuator is operable to cover a light-transmitting region of the transparent substrate, and
wherein shutter module is disposed such that the roll-up actuator is between the image sensor module and the transparent substrate.

6. The image pickup device of claim 1, wherein each of the one or more electronic devices comprises:
a pair of electrode pads formed at lateral potions of the electronic device, and
a pair of plate springs which electrically connect the pair of electrode pads to the second interconnection pad.

7. The image pickup device of claim 6, wherein each plate spring is a bumped plate spring, and a protruding portion of the bumped plate spring contacts the pair of electrode pads or the second interconnection pad.

8. The image pickup device of claim 6, further comprising:
a housing disposed on the printed circuit board, wherein the image sensor module and the wafer scale lens module are disposed and fixed within the housing, and wherein each plate spring is fixed at a lateral wall of the housing.

9. The image pickup device of claim 1, wherein each of the one or more electronic devices comprises:
a pair of electrode pads formed at each side of the one or more electronic devices, wherein the pair of electrode pads are electrically connected to the second interconnection pad through a conductive through via that penetrates the image sensor module and the fixed optical system.

10. The image pickup device of claim 1, wherein the fixed optical system comprises an optical lens module comprising:
a plurality of substrates spaced from each other, and
a lens element attached to one or both sides of each of the plurality of substrates.

11. An image pickup device comprising:
a printed circuit board (PCB) comprising inner interconnection pads, a pair of first outer interconnection pads, and a pair of second outer interconnection pads;
an image sensor module mounted on the PCB and electrically connected to the inner interconnection pads;
an optical lens module disposed over the image sensor module and comprising one or more lenses;
a fluidic lens module disposed over the optical lens module, and electrically connected to the pair of first outer interconnection pads, wherein the fluidic lens module has a variable focal length; and
a shutter module disposed over the fluidic lens module and electrically connected to the pair of second outer interconnection pads.

12. The image pickup device of claim 11, wherein the fluidic lens module comprises a transparent substrate and a lens part mounted on the transparent substrate, and
the fluidic lens module is disposed such that the lens part is disposed between the transparent substrate and the image sensor.

13. The image pickup device of claim 11, wherein the shutter module comprises:
a transparent substrate, and
a roll-up actuator disposed on the transparent substrate and operable to cover a light-transmitting region of the transparent substrate, and
the shutter module is disposed such that the roll-up actuator is disposed between the image sensor module and the transparent substrate.

14. The image pickup device of claim 11, further comprising:
a housing disposed between the inner interconnection pads and the pairs of first and second outer interconnection pads on the PCB, wherein the image sensor module and the optical lens module are disposed and fixed within the housing.

15. The image pickup device of claim 14, wherein each of the fluidic lens module and the shutter module comprises a pair of electrode pads formed at lateral portions thereof, the image pickup device further comprising two pairs of connectors electrically connecting the pair of electrode pads to the pairs of first and second outer interconnection pads.

16. The image pickup device of claim 15, wherein each connector comprises a bumped plate spring.

17. The image pickup device of claim 16, wherein each bumped plate spring is fixed at a lateral wall of the housing.

18. The image pickup device of claim 11, wherein a distance between the optical lens module and the image sensor module and a distance between lenses included in the optical lens module are fixed.

19. A method of manufacturing an image pickup device, comprising:
preparing a printed circuit board (PCB) comprising inner interconnection pads, a pair of first outer interconnection pads and a pair of second interconnection pads;
mounting an image sensor module on the PCB, and electrically connecting the image sensor module to the inner interconnection pads;
fixing a housing between the inner interconnection pads and the pairs of first and second outer interconnection pads, wherein the housing comprises two pairs of connectors attached to lateral walls thereof;
disposing an optical lens module over the image sensor module inside the housing, wherein the optical lens module comprises one or more lenses;
disposing a fluid lens module over the housing, and electrically connecting the fluid lens module to the pair of first interconnection pads through a first of the two pairs of connectors, wherein the fluid lens module has a variable focus; and
disposing a shutter module over the fluidic lens module, and electrically connecting the shutter module to the pair of second outer interconnection pads through a second of the two pairs of connectors.
